(19) United States
(12) Patent Application Publication
(10) Pub. No.: US 2026/0024958 A1
(43) Pub. Date: Jan. 22, 2026

(54) SURFACE-EMITTING LASER

(71) Applicant: Hangzhou GClight Semiconductor Technology Co. Ltd, Hangzhou (CN)

(72) Inventors: Ziye WANG, Hangzhou (CN); Cunzhu TONG, Hangzhou (CN); Kaidi CAI, Hangzhou (CN)

(21) Appl. No.: 19/344,270

(22) Filed: Sep. 29, 2025

Related U.S. Application Data
(63) Continuation of application No. PCT/CN2025/111766, filed on Jul. 31, 2025.

(30) Foreign Application Priority Data
Jun. 18, 2025 (CN) 202510820085.6

(51) Int. Cl. H01S 5/11; H01S 5/183

(52) U.S. Cl. CPC H01S 5/11; H01S 5/183

(57) ABSTRACT

A surface-emitting laser includes a substrate and an epitaxial structure, in which the substrate and the epitaxial structure are stackedly arranged. The epitaxial structure includes a plurality of holes. A section of each of the plurality of holes parallel to the substrate is configured to be T-shaped. The hole is filled with a filler, and a refractive index of the filler is different from a refractive index of the epitaxial structure. Under the same modal field area and surface-emitting coupling efficiency, the surface-emitting laser in the present disclosure exhibits a larger threshold gain difference between the fundamental mode and a higher-order resonant mode, resulting in superior single-mode operation stability. The fabrication difficulty of the hole with a T-shaped structure is relatively low.

### CROSS-REFERENCE TO RELATED APPLICATIONS

This application a continuation of International Patent Application No. PCT/CN2025/111766, filed on Jul. 31, 2025, which claims the benefit of priority from Chinese Patent Application No. 202510820085.6, field on Jun. 18, 2025. The content of the aforementioned application, including any intervening amendments thereto, is incorporated herein by reference in its entirety.

### TECHNICAL FIELD

This application relates to semiconductor lasers, and more particularly to a surface-emitting laser.

### BACKGROUND

Semiconductor lasers have been widely adopted in various fields such as laser processing, communication and lighting due to their compact size, high electro-optic conversion efficiency and low cost. However, traditional edge-emitting lasers or vertical cavity surface-emitting semiconductor lasers typically exhibit a large far-field divergence angle in the single-mode operation, which complicates the optical path design and system integration, thereby raising overall system costs and reducing the operational reliability.

To address this issue, a photonic crystal surface-emitting laser (PCSEL) has been designed, which has a reduced far-field divergence angle. Nevertheless, a photonic crystal resonant cavity of the PCSEL struggles with high fabrication difficulty and poor single-mode stability. Therefore, there is an urgent need to provide a semiconductor laser with excellent single-mode stability and low fabrication difficulty.

### SUMMARY

The present disclosure provides a surface-emitting laser to address the problem that the existing lasers struggle with poor single-mode stability and complicated fabrication process.

The present disclosure provides a surface-emitting laser, comprising:
a stacked substrate; and
an epitaxial structure;
wherein the substrate and the epitaxial structure are stackedly arranged; the epitaxial structure is provided with a plurality of holes; and a section of each of the plurality of holes parallel to the substrate is configured to be T-shaped; each of the plurality of holes is filled with a filler; and a refractive index of the filler is different from a refractive index of the epitaxial structure.

Compared to the existing hole structure formed by an ellipse-circle combination or large circle-small circle combination, each of the plurality of holes with a T-shaped section provided in the epitaxial structure of the present disclosure have reduced fabrication difficulty. Since the section of the hole is T-shaped, after the hole is filled with the filler, a shape of the filler inside the hole is also T-shaped. The refractive index of the filler is different from the refractive index of the epitaxial structure. Compared to a hole with an isosceles triangle-shaped section in the prior art, under the same modal field area and surface-emitting coupling efficiency, the surface-emitting laser in the present disclosure exhibits a larger threshold gain difference between the fundamental mode and a higher-order resonant mode, resulting in superior single-mode operation stability.

In an embodiment, the epitaxial structure comprises a photonic crystal layer and a p-doped cladding layer; the photonic crystal layer and the p-doped cladding layer are stackedly arranged; and the plurality of holes are provided on the photonic crystal layer.

In an embodiment, each of the plurality of holes is configured to at least partially extend to the p-doped cladding layer.

In an embodiment, the photonic crystal layer comprises a plurality of unit cells arranged in a lattice pattern. The plurality of unit cells are periodically arranged along a first direction and a second direction; each of the plurality of unit cells contains one of the plurality of holes; the section of each of the plurality of holes is symmetrical along a third direction, the first direction, the second direction and the third direction are all parallel to the substrate; the first direction is perpendicular to the second direction. The third direction is at an angle of 45° to both the first direction and the second direction.

In an embodiment, a depth of each of the plurality of holes along a direction perpendicular to the substrate is d, and 50 nm≤d≤500 nm.

In an embodiment, the section of each of the plurality of holes comprises a first portion and a second portion connected to each other, and an area of the first portion is larger than an area of the second portion.

In an embodiment, a length L₁ of the first portion satisfies 0.35a≤L₁≤1.1a, and a width H₁ of the first portion satisfies 0.1a≤H₁≤0.65a, a length L₂ of the second portion satisfies 0.05a≤L₂≤0.35a, and a width H₂ of the second portion satisfies 0.05a≤H₂≤0.35a, wherein a is a lattice constant.

In an embodiment, the first portion is elliptical, and the second portion is rectangular; the length L₁ of the first portion satisfies 0.55a≤L₁≤0.85a; the width H₁ of the first portion satisfies 0.2a≤H₁≤0.5a; the length L₂ of the second portion satisfies 0.1a≤L₂≤0.35a; and the width H₂ of the second portion satisfies 0.1a≤H₂≤0.35a.

In an embodiment, the first portion is rhombus-shaped, and the second portion is rectangular; the length L₁ of the first portion satisfies 0.7a≤L₁≤1.1a; the width H₁ of the first portion satisfies 0.3a≤H₁≤0.65a; the length L₂ of the second portion satisfies 0.1a≤L₂≤0.35a; and the width H₂ of the second portion satisfies 0.05a≤H₂≤0.3a.

In an embodiment, the first portion and the second portion are both rectangular; the length L₁ of the first portion satisfies 0.5a≤L₁≤0.8a; the width H₁ of the first portion satisfies 0.1a≤H₁≤0.4a; the length L₂ of the second portion satisfies 0.1a≤L₂≤0.35a; and the width H₂ of the second portion satisfies 0.1a≤H₂≤0.35a.

In an embodiment, the first portion is roughly elliptical, comprising two straight edges opposite to each other and two curved edges opposite to each other; the two curved edges are each configured to be curved inward, and have a radian of 0-2 rad; the second portion is rectangular; the length L₁ of the first portion satisfies 0.35a≤L₁≤0.85a; the width H₁ of the first portion satisfies 0.15a≤H₁≤0.4a; the length L₂ of the second portion satisfies 0.1a≤L₂≤0.35a; and the width H₂ of the second portion satisfies 0.1a≤H₂≤0.35a.

### BRIEF DESCRIPTION OF THE DRAWINGS

FIG. 1 structurally shows a single-mode photonic crystal resonant cavity in the prior art;

FIG. 2 structurally shows another single-mode photonic crystal resonant cavity in the prior art;

FIG. 3 structurally shows another single-mode photonic crystal resonant cavity in the prior art;

FIG. 4 structurally shows a surface-emitting laser according to an embodiment of the present disclosure;

FIG. 5 is a sectional view of an epitaxial structure according to an embodiment of the present disclosure (parallel to a substrate);

FIG. 6 structurally shows another surface-emitting laser according to an embodiment of the present disclosure;

FIG. 7 structurally shows another surface-emitting laser according to an embodiment of the present disclosure;

FIG. 8 is a top view of the surface-emitting laser according to an embodiment of the present disclosure;

FIG. 9 structurally shows another surface-emitting laser according to an embodiment of the present disclosure;

FIG. 10 is a top view of the surface-emitting laser according to an embodiment of the present disclosure;

FIG. 11 is a sectional view of FIG. 5 along A-A′;

FIG. 12 shows a mode threshold gain diagram of the surface-emitting laser according to an embodiment of the present disclosure;

FIG. 13 shows a vertical radiation constant diagram of the surface-emitting laser according to an embodiment of the present disclosure;

FIG. 14 shows a resonant mode distribution diagram of the surface-emitting laser according to an embodiment of the present disclosure;

FIG. 15 shows a far-field pattern corresponding to a fundamental mode of the surface-emitting laser according to an embodiment of the present disclosure;

FIG. 16 shows a near-field pattern corresponding to a fundamental mode of the surface-emitting laser according to an embodiment of the present disclosure;

FIG. 17 shows a resonant mode distribution diagram of a laser in the prior art;

FIG. 18 is a sectional view of the epitaxial structure according to another embodiment of the present disclosure (parallel to the substrate);

FIG. 19 is a sectional view of the epitaxial structure according to another embodiment of the present disclosure (parallel to the substrate);

FIG. 20 is a sectional view of the epitaxial structure according to another embodiment of the present disclosure (parallel to the substrate); and

FIG. 21 is a sectional view of the epitaxial structure according to another embodiment of the present disclosure (parallel to the substrate).

In the figures: 10—substrate; 20—epitaxial structure; 201—hole; 202—filler; 1—n-doped cladding layer; 2—active layer; 3—photonic crystal layer; 4—p-doped cladding layer; 5—p-doped contact layer; 6—first metal film; 7—second metal film; 8—electrical insulation layer; 9—transparent conductive layer; 2011—first portion; and 2012—second portion.

### DETAILED DESCRIPTION OF EMBODIMENTS

In order to make the objects, technical solution and advantages clearer, the present disclosure will be further illustrated below in detail with reference to the accompanying drawings and the embodiments.

As used herein, terms are merely for the purpose of describing specific embodiments, and are not intended to limit the present disclosure. As used herein, unless otherwise specified, singular-form expressions involving “a”, “an”, “the”, “above”, “said” and “this” are intended to cover the meaning of “one or more”.

As used herein, “an embodiment”, “specific embodiments” or similar phrases mean that a specific feature, structure or characteristic described with reference to the embodiment is included in one or more embodiments of the present disclosure. The terms “comprise”, “include”, “have” and any variations thereof are intended to mean “include but are not limited to”, unless otherwise specified.

Mode field refers to a cross-sectional distribution pattern of an electromagnetic field of a fundamental mode in an optical waveguide or a laser, reflecting spatial concentration degree and propagation characteristics of optical energy. The mode field distribution directly affects the divergence angle and luminance of light beams. Specifically, the smaller the mode field's diameter, the stronger the diffraction effect, indicating a larger far-field divergence angle.

Since the traditional edge-emitting lasers or vertical cavity surface-emitting semiconductor lasers have a smaller single-mode modal area, the far-field divergence angle is larger in the single-mode operation, usually above 10°. In the photonic crystal surface-emitting lasers, a two-dimensional photonic crystal is served as a resonant cavity to achieve the laser oscillation and surface-emitting output, and enable stable single-mode operation in the mode filed with a relatively large area (such as with a diameter of above 500 μm), while maintaining a far-field divergence angle of less than 1°, thereby significantly reducing the far-field divergence angle of the laser.

The photonic crystal refers to a periodic dielectric structural material with a photonic bandgap. The photonic bandgap arises from the spatial periodicity of dielectric constants caused by the periodic arrangement of materials with different dielectric constants, and results in a periodic distribution of optical refractive indices, generating an energy band structure for light propagation within it, where photons whose frequencies fall within the photonic bandgap are prohibited from propagating. This special optical characteristic is determined by the configuration of the electromagnetic field in the photonic crystal, such that the light transmission can be controlled through deliberate design of the photonic crystal's structure.

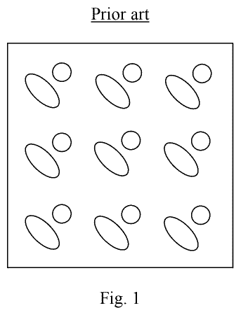

In the design of the photonic crystal resonant cavity, it is necessary to precisely control geometric parameters and structural configuration of the photonic crystal to ensure a significant threshold gain difference between the fundamental mode and the higher-order resonant mode within the resonant cavity. Several single-mode photonic crystal resonant cavities in the prior art are structurally shown in FIGS. 1-3.

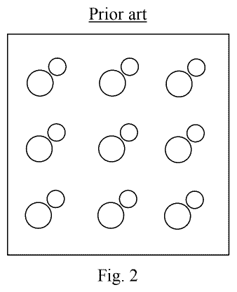

Referring to FIGS. 1-2, there are main two structures of the single-mode photonic crystal resonant cavity in the prior art. one of the two structures of the photonic crystal is based on a dual-lattice structure, usually adopting a hole structure formed by an ellipse-circle combination (as shown in FIG. 1) or large circle-small circle combination (as shown in FIG. 2), whose requirements for hole pitches and sizes of the unit cells in the photonic crystal are extremely strict, with fabrication tolerance of only a few nanometers. In addition, an etching process at a micro-nano scale places higher demands on precisely controlling hole shapes and sizes, making it difficult to control distribution differences between hole depths in the dual-lattice structure. This directly affects subsequent batch processing (such as a nanoimprint), thereby seriously struggling with fabrication reliability.

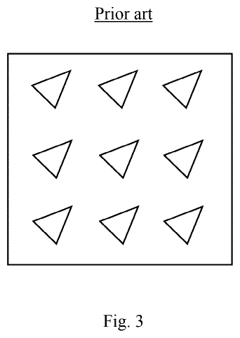

Referring to FIG. 3, one of the two structures of the photonic crystal is based on an isosceles triangle structure. This design is more ideal than the dual-lattice structure in the fabrication difficulty and stability. Under the same modal field area and surface-emitting coupling efficiency, the design exhibits a smaller threshold gain difference between the fundamental mode and a higher-order resonant mode, resulting in worse single-mode stability.

In view of this, the embodiments in this present disclosure provide a surface-emitting laser to address the problem that the existing lasers struggle with poor single-mode stability and complicated fabrication process. The embodiments of the present disclosure are described in detail with reference to the accompanying drawings as follows.

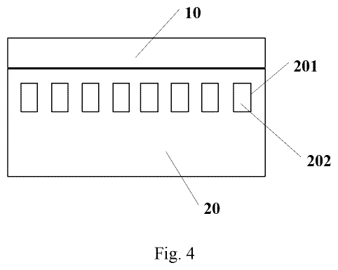

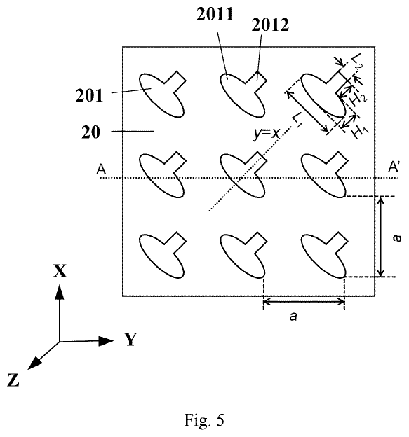

A surface-emitting laser according to an embodiment of the present disclosure is structurally shown in FIG. 4. A sectional view of an epitaxial structure according to an embodiment of the present disclosure is shown in FIG. 5 (parallel to a substrate). As shown in FIGS. 4-5, the present disclosure provides a surface-emitting laser, including a substrate 10 and an epitaxial structure 20, in which the substrate 10 and the epitaxial structure 20 are stackedly arranged. The epitaxial structure 20 is provided with a plurality of holes 201, and a section of each of the plurality of holes 201 parallel to the substrate 10 is configured to be roughly T-shaped. Each of the plurality of holes 201 is filled with a filler 202, and a refractive index of the filler 202 is different from a refractive index of the epitaxial structure 20.

Compared to the existing hole structure formed by an ellipse-circle combination or large circle-small circle combination (shown in FIGS. 1-2), each of the plurality of holes 201 with a T-shaped section provided in the epitaxial structure 20 of the present disclosure have reduced fabrication difficulty. Since the section of the hole 201 is T-shaped, after the hole 201 is filled with the filler 202, a shape of the filler 202 inside the hole 201 is also T-shaped. The refractive index of the filler 202 is different from the refractive index of the epitaxial structure 20. Compared to a hole with an isosceles triangle-shaped section in the prior art (shown in FIG. 3), under the same modal field area and surface-emitting coupling efficiency, the surface-emitting laser in the present disclosure exhibits a larger threshold gain difference between the fundamental mode and a higher-order resonant mode, resulting in superior single-mode stability.

In an embodiment, the filler 202 can be a gas, such as air, nitrogen and so on. The hole 201 can be filled with semiconductor materials selected from the group consisting of metal materials and insulator materials.

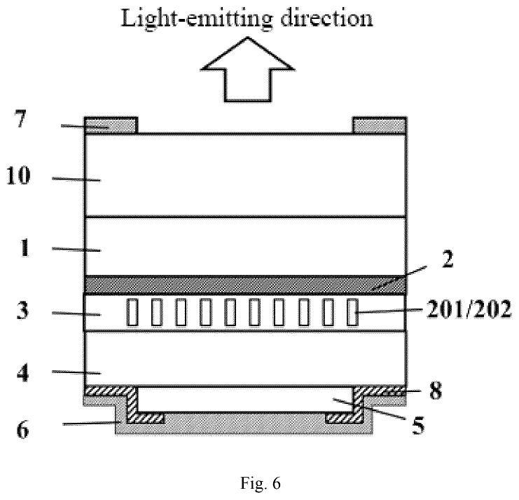

Another surface-emitting laser according to an embodiment of the present disclosure is structurally shown in FIG. 6. According to the embodiment shown in FIG. 6, the substrate 10 can be a n-doped substrate, and the epitaxial structure 20 includes a plurality of epitaxial layers stackedly arranged.

In some embodiments, the epitaxial structure 20 includes a n-doped cladding layer 1, an active layer 2, a photonic crystal layer 3, a p-doped cladding layer 4 and a p-doped contact layer 5 stackedly arranged in sequence. The n-doped cladding layer 1, the active layer 2, the photonic crystal layer 3, the p-doped cladding layer 4 and the p-doped contact layer 5 are all the epitaxial layers. The photonic crystal layer 3 is the resonant cavity of the laser to adjust an internal light field of the laser and construct a resonant cavity mode with a relatively large threshold gain difference. The material of the photonic crystal layer 3 is selected from the group consisting of GaAs, InP, AlGaAs, GaAsP, InAlGaAs and InGaAsP. The active layer 2 is used to perform a continuous light amplification on the resonator mode of the selected fundamental mode. The material of the active layer 2 adopts a semiconductor material selected from the group consisting of quantum well materials, quantum dot materials, and quantum cascade structure materials, and specifically InGaAs multiple quantum well materials. The material of the p-doped cladding layer 4 is Al_{0.4}Ga_{0.6}As. The material of the p-doped contact layer 5 is GaAs. The material of the n-doped cladding layer 1 is Al_{0.6}Ga_{0.4}As.

According to different spatial dimensions of periodic changes in the refractive index, the photonic crystal can be classified into one-dimensional photonic crystal, two-dimensional photonic crystal and three-dimensional photonic crystal. In the embodiments of the present disclosure, the photonic crystal layer 3 is the two-dimensional photonic crystal, and the holes 201 are provided in the photonic crystal layer 3. The special structural design with the T-shaped filler 202 can adjust the internal light field of the laser and construct the resonant cavity mode with the relatively large threshold gain difference.

It has been proved by experiments, compared to the filler 202 with the geometric patterns such as traditional circles and rectangles, the photonic crystal layer 3 in the present disclosure is provided with the T-shaped filler 202, thereby significantly enhancing a selectivity of the photonic crystal resonant cavity for different resonant modes. In this case, the structure effectively suppresses a destructive interference effect of the oscillating light field in the resonant cavity and significantly improves a ratio of laser vertical coupling output. The surface-emitting laser based on the structure of the photonic crystal layer 3 can maintain single-mode characteristics of the device under a relatively large modal field area, thereby achieving a surface-emitting laser output of high power single-mode.

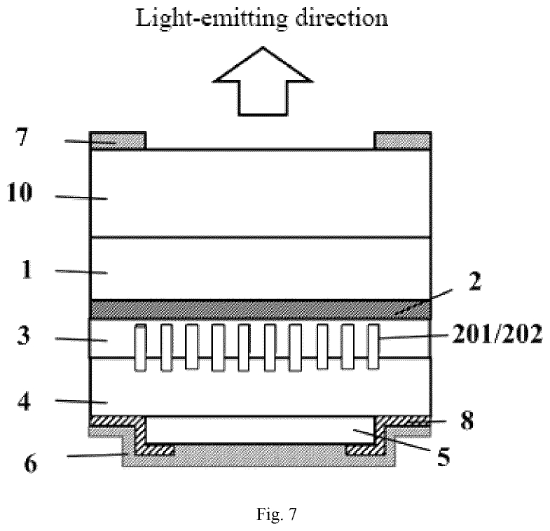

Another surface-emitting laser according to an embodiment of the present disclosure is structurally shown in FIG. 7. According to the embodiment of FIG. 7, each of the plurality of holes 201 is configured to at least partially extend to the p-doped cladding layer 4. The holes 201 are provided in the photonic crystal layer 3 and the p-doped cladding layer 4, and the filler 202 is simultaneously provided in the photonic crystal layer 3 and the p-doped cladding layer 4. When preparing the holes 201, the holes 201 are configured to extend from the photonic crystal layer 3 to the p-doped cladding layer 4 along a vertical direction of the substrate 10. Correspondingly, the filler 202 is also configured to extend to the p-doped cladding layer 4. A ratio of light field distribution inside the hole 201 is improved by extending the hole 201 to the p-doped cladding layer 4 to deepen the hole 201, thereby achieving a better single-mode control of optical modes in the resonant cavity.

Referring to the embodiment in FIG. 5, the photonic crystal layer 3 includes a plurality of unit cells arranged in a lattice pattern. The plurality of unit cells are periodically arranged along a first direction X and a second direction Y. Each of the plurality of unit cells (e.g. each arranged unit) in the photonic crystal layer 3 contains one of the holes 201 and the corresponding filler 202. The refractive index of the filler 202 is different from that of the base material of the photonic crystal layer 3. The section of each hole 201 is symmetrical along a third direction Z, and the section is parallel to the substrate 10. The first direction X, the second direction Y and the third direction Z are all parallel to the substrate 10. The first direction X is perpendicular to the second direction Y, and the third direction Z is at an angle of 45° to both the first direction X and the second direction Y.

In other words, the section is a T-shaped pattern as well as an axial symmetry pattern, and the angle between an axis of symmetry and the first direction X or the second direction Y is 45°. The pattern is formed by connecting two geometric patterns, such as an ellipse-circle combination, in which the area of the ellipse is larger than the area of the rectangle. By adopting this design method of introducing additional small-sized structures (such as rectangles) on basic shapes with rotational symmetry (such as ellipses), it is possible to achieve fine adjustments of the electromagnetic field distribution in the resonant mode within the photonic crystal resonant cavity (such as the symmetry of the electromagnetic field distribution, and the positions of the wave abdomen and nodes of the electromagnetic field). This further enhances the selectivity of the fundamental mode and higher-order modes in the photonic crystal cavity, achieving stable single-mode resonance of the laser with a large area. In addition, this structure can effectively increase the vertical radiation loss of the photonic crystal cavity, which is conducive to increasing the surface-emitting output power and slope efficiency of the laser.

The photonic crystal layer 3 has a plurality of square lattices. In other words, there is the same lattice constant a in two mutually perpendicular periodic arrangement directions (the first direction X and the second direction Y). The lattice constant is approximately equal to a lasing wavelength λₙ of the laser provided in the embodiment in materials. In this embodiment, the lattice constant can be set as 298 nm, and the desired operating wavelength of the corresponding laser is approximately 980 nm.

In an embodiment, the photonic crystal layer 3 is a square, and a side length of the photonic crystal layer 3 is 600 μm.

In some embodiments, a diameter of the photonic crystal layer 3 is configured to be 1 nm or 3 nm according to design requirements for different output powers of the lasers.

Referring to the embodiment in FIG. 6, a first metal film 6 is provided on a side of the p-doped contact layer 5 and the side is away from the p-doped cladding layer 4. A second metal film 7 is provided on a side of the n-doped substrate 10 and the side is away from the n-doped cladding layer 1. The first metal film 6 and the second metal film 7 are prepared via the deposition processes. The first metal film 6 is Ti/Pt/Au composite metal film and the second metal film 7 is Ni/Au—Ge/Ni/Au composite metal film. The first metal film 6 and the second metal film 7 are electrically conductive to allow current to be introduced into the laser.

In an embodiment, the p-doped contact layer 5 is combined with the p-doped cladding layer 4 to form a p-doped semiconductor material layer. The p-doped cladding layer 4 and the p-doped contact layer 5 are arranged in a stepped form, where the area of the p-doped contact layer 5 is smaller than the area of the p-doped cladding layer 4, and the p-doped contact layer 5 is arranged at a center of the p-doped cladding layer 4. The first metal film 6 is wrapped around the p-doped semiconductor material layer on the side away from the substrate 10. An electrical insulation layer 8 is provided between the first metal film 6 and the p-doped semiconductor material layer, and the electrical insulation layer 8 is arranged at an edge of the p-doped semiconductor material layer. The material of the electrical insulation layer 8 is silicon oxide or silicon nitride. By arranging the electrical insulation layer 8 in the edge of the device, the current along the edge path can be blocked, allowing the current to be introduced at the central region of the device.

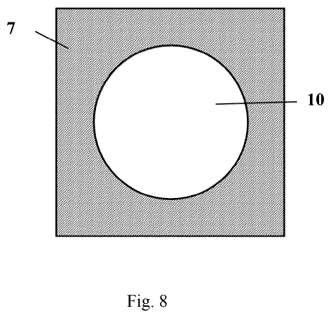

A top view of the surface-emitting laser according to an embodiment of the present disclosure is shown in FIG. 8. According to the embodiment in FIGS. 6-8, a light-emitting hole is provided at a center of the second metal film 7. The light-emitting hole is circular or square. The present disclosure is not intended to limit the shape of the light-emitting hole. In this embodiment, a direction of the laser output is from a substrate side.

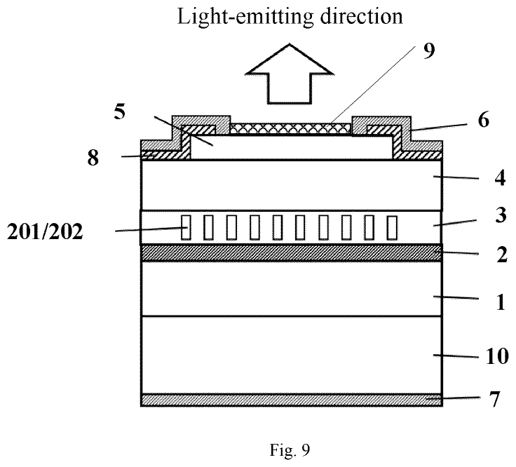

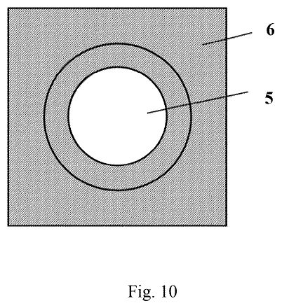

Another surface-emitting laser according to an embodiment of the present disclosure is structurally shown in FIG. 9. A top view of the surface-emitting laser according to an embodiment of the present disclosure is shown in FIG. 10. According to another embodiment in FIGS. 9-10, the light-emitting hole is provided at a center of the first metal film 6. The light-emitting hole is circular or square. The present disclosure is not intended to limit the shape of the light-emitting hole. In this embodiment, the direction of the laser output is from an epitaxial side. A transparent conductive layer 9 is provided at a corresponding position of the light-emitting hole in the p-doped contact layer 5. The transparent conductive layer 9 not only allows current to pass through and be better introduced into the device, but also does not shield the light output of the device.

In an embodiment, the depth of the hole 201 along a vertical direction of the substrate 10 is d, and 50 nm≤d≤500 nm. By precisely adjusting the depth of the hole structure and optimizing the light field limiting factors and mode loss, the single-mode operating conditions of the laser under different epitaxial layer configurations are better satisfied.

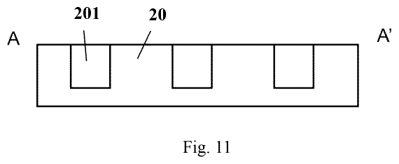

A sectional view of FIG. 5 along A-A′ is shown in FIG. 11. According to the embodiment in FIG. 11, a depth direction of the hole 201 is along the vertical direction of the substrate 10. The section of the hole 201 is rectangular, conical (not shown in FIG. 11), trapezoidal (not shown in FIG. 11) or drop-shaped (not shown in FIG. 11), and preferably, the section of the hole 201 is rectangular.

The section of the hole 201 parallel to the substrate 10 is described in detail as follows.

Referring to the embodiment in FIG. 5, the section includes a first portion 2011 and a second portion 2012, where the first portion 2011 and the second portion 2012 are connected to each other. An area of the first portion 2011 is larger than an area of the second portion 2012. Along a vertical direction of the third direction Z, a length L₁ of the first portion 2011 satisfies 0.35a≤L₁≤1.1a, L₁ and a length L₂ of the second portion 2012 satisfies 0.05a≤L₂≤0.35a. Along the third direction Z, a width H₁ of the first portion 2011 satisfies 0.1a≤H₁≤0.65a, and a width H₂ of the second portion 2012 satisfies 0.05a≤H₂≤0.35a, where a is a lattice constant. L₁ can be 0.35a, 0.4a, 0.5a, 0.7a, 1.0a or 1.1a, but is not limited to the aforementioned values. H₁ can be 0.1a, 0.2a, 0.4a, 0.5a, 0.6a or 0.65a, but is not limited to the aforementioned values. L₂ can be 0.05a, 0.1a, 0.15a, 0.2a, 0.3a or 0.35a, but is not limited to the aforementioned values. H₂ can be 0.05a, 0.la, 0.15a, 0.2a, 0.3a or 0.35a, but is not limited to the aforementioned values.

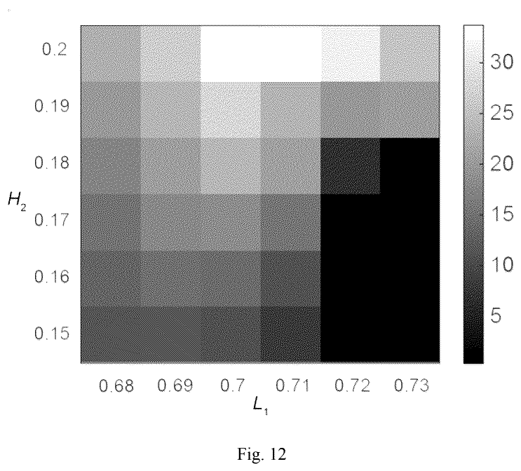

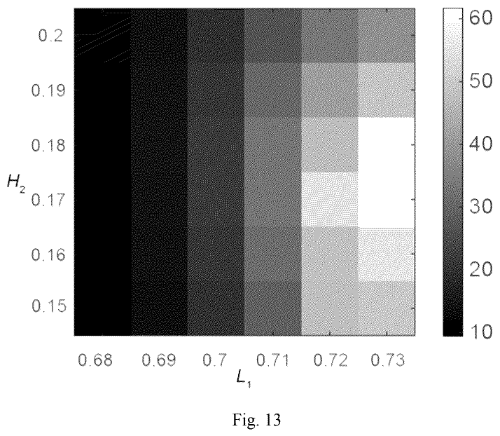

A mode threshold gain diagram of a surface-emitting laser according to an embodiment of the present disclosure is shown in FIG. 12. According to the embodiment combined FIG. 5, FIG. 12 and FIG. 13, the first portion 2011 is elliptical, and the second portion 2012 is rectangular. The length L₁ of the first portion 2011 satisfies 0.55a≤L₁≤0.85a. The width H₁ of the first portion 2011 satisfies 0.2a≤H₁≤0.5a. The length L₂ of the second portion 2012 satisfies 0.1a≤L₂≤0.35a. The width H₂ of the second portion 2022 satisfies 0.1a≤H₂≤0.35a.

In an embodiment, the width H₁ of the ellipse is set as 0.39a, and the length L₂ of the rectangle is set as 0.18a. Among the two structural parameters (H₂ and L₁) as variables, the mode threshold gain difference of the laser is mainly affected by the width H₂ of the rectangle, but the vertical radiation constant is more influenced by the length L₁ of the ellipse. When the length L₁ of the ellipse is 0.7a and the width H₂ of the rectangle is 0.2a, the mode threshold gain difference of the laser reaches a maximum value of 33 cm⁻¹, and the vertical radiation constant is moderate, approximately 20 cm⁻¹. In addition, it can be found that within a large adjustment range, the mode threshold gain difference of the laser can maintain a relatively large value, thereby supporting the high power single-mode operation of the device. L₁ can be 0.55a, 0.6a, 0.65a, 0.75a, 0.8a or 0.85a, but is not limited to the aforementioned values. H₁ can be 0.2a, 0.25a, 0.3a, 0.35a, 0.4a, 0.45a or 0.5a, but is not limited to the aforementioned values. L₂ can be 0.1a, 0.15a, 0.2a, 0.25a, 0.3a or 0.35a, but is not limited to the aforementioned values. H₂ can be 0.1a, 0.15a, 0.25a, 0.3a or 0.35a, but is not limited to the aforementioned values.

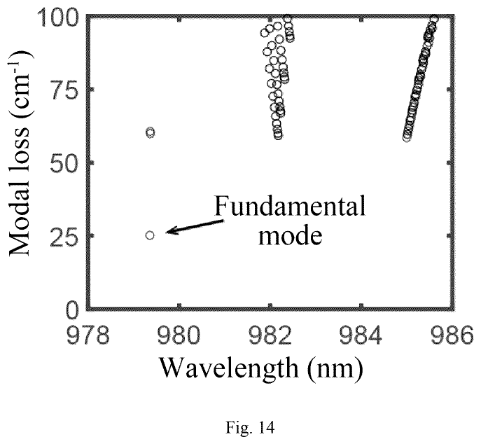

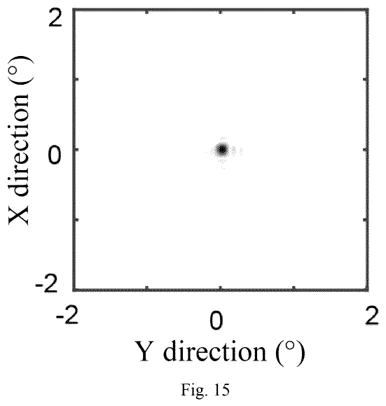

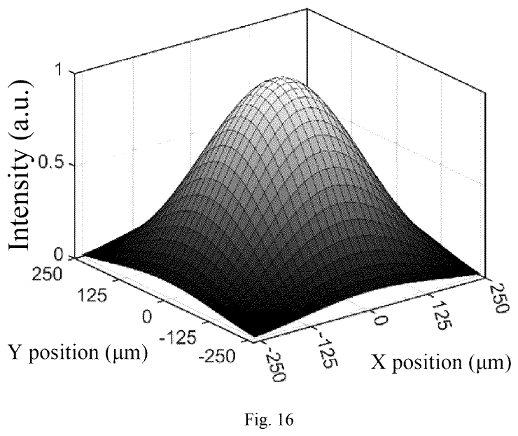

A resonant mode distribution diagram of a surface-emitting laser according to an embodiment of the present disclosure is shown in FIG. 14. A far-field and near-field pattern corresponding to a fundamental mode of a surface-emitting laser according to an embodiment of the present disclosure are shown in FIGS. 15-16, respectively. Referring to FIGS. 14-16, regarding of the structure in the above embodiments, the corresponding resonant mode distribution and the far-field and near-field patterns corresponding to the fundamental mode are calculated. The circle indicated by an arrow in FIG. 14 is the fundamental mode. The fundamental mode is the lowest-order mode transmitted in the waveguide structure, featuring a unique optical field distribution and transmission characteristics. In the semiconductor lasers, the fundamental mode is typically exhibited as a light spot of energy distribution on the cross section, while the higher-order mode has a plurality of the light spots on the cross section. In the semiconductor lasers, besides the fundamental modes, there are also higher-order modes. The energy distribution of the high-order mode on the cross section has a plurality of the light spots.

As shown in FIG. 14, there is a significant difference in threshold gain between the fundamental mode with the lowest threshold gain (the circle indicated by the arrow in the left column) and other modes (such as the high-order modes in the middle column and the high-order modes in the right column). This structure maintains a far-field divergence angle of less than 1° (as shown in FIG. 15), and has a gaussian distribution of the intracavity electromagnetic field intensity (as shown in FIG. 16).

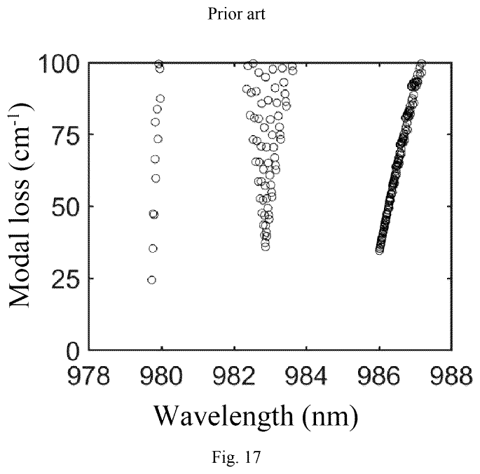

A resonant mode distribution diagram of a laser in the prior art is shown in FIG. 17. A photonic crystal structure with an isosceles triangle-shaped section in the prior art is shown in FIG. 3. As shown in FIG. 14, combining FIG. 3, FIG. 14 and FIG. 17 as a comparative example, under the same resonant cavity size, the mode threshold gain difference of the comparative example is much smaller than that of the embodiments in the present disclosure.

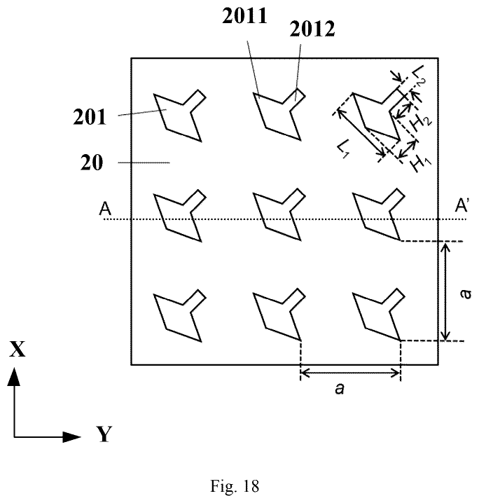

A sectional view of the epitaxial structure according to another embodiment of the present disclosure is shown in FIG. 18 (parallel to the substrate). According to the embodiment in FIG. 18, the first portion 2011 is rhombus-shaped, and the second portion 2012 is rectangular. The length L₁ of the first portion 2011 satisfies 0.7a≤L₁≤1.1a; the width H₁ of the first portion 2011 satisfies 0.3a<H₁<0.65a. The length L₂ of the second portion 2012 satisfies 0.1a≤L₂≤0.35a. The width H₂ of the second portion 2012 satisfies 0.05a≤H₂≤0.3a. L₁ can be 0.7a, 0.8a, 0.9a, 1.0a or 1.1a, but is not limited to the aforementioned values. H₁ can be 0.3a, 0.35a, 0.4a, 0.5a, 0.6a or 0.65a, but is not limited to the aforementioned values. L₂ can be 0.1a, 0.2a, 0.3a or 0.35a, but is not limited to the aforementioned values. H₂ can be 0.05a, 0.1a, 0.2a or 0.3a, but is not limited to the aforementioned values.

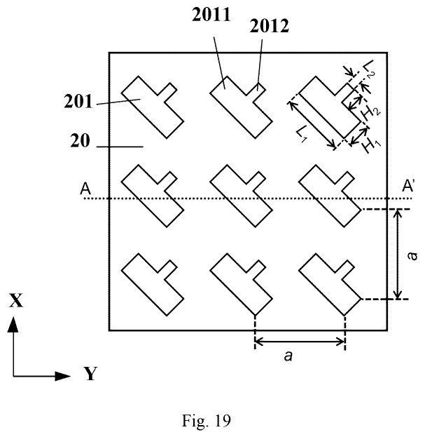

A sectional view of the epitaxial structure according to another embodiment of the present disclosure is shown in FIG. 19 (parallel to the substrate). The first portion 2011 the second portion 2012 are both rectangular. The length L₁ of the first portion 2011 satisfies 0.5a≤L₁≤0.8a. The width H₁ of the first portion 2011 satisfies 0.1a≤H₁≤0.4a. The length L₂ of the second portion 2012 satisfies 0.1a≤L₂≤0.35a. The width H₂ of the second portion 2012 satisfies 0.1a≤H₂≤0.35a. L₁ can be 0.5a, 0.6a, 0.7a or 0.8a, but is not limited to the aforementioned values. H₁ can be 0.1a, 0.2a, 0.3a or 0.4a, but is not limited to the aforementioned values. L₂ can be 0.1a, 0.2a, 0.3a or 0.35a, but is not limited to the aforementioned values. H₂ can be 0.1a, 0.2a, 0.3a or 0.35a, but is not limited to the aforementioned values.

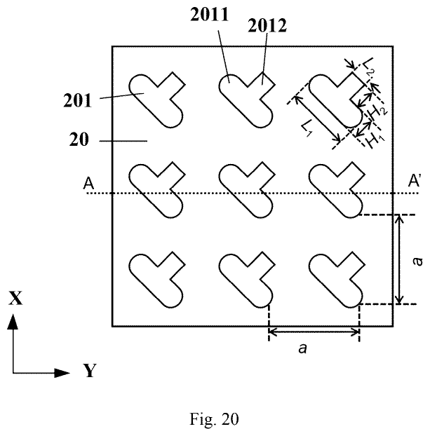

A sectional view of the epitaxial structure according to another embodiment of the present disclosure is shown in FIG. 20 (parallel to the substrate). The first portion 2011 is roughly elliptical, including two straight edges opposite to each other and two curved edges opposite to each other. The two curved edges are each configured to be curved inward as like a runway and have a radian of 0-2 rad. The second portion 2012 is rectangular. The length L₁ of the first portion 2011 satisfies 0.35a≤L₁≤0.85a. The width H₁ of the first portion 2011 satisfies 0.15a≤H₁≤0.4a. The length L₂ of the second portion 2012 satisfies 0.1a≤L₂≤0.35a. The width H₂ of the second portion 2012 satisfies 0.1a≤H₂≤0.35a. L₁ can be 0.35a, 0.4a, 0.5a, 0.6a, 0.7a, 0.8a or 0.85a, but is not limited to the aforementioned values. H₁ can be 0.15a, 0.2a, 0.3a or 0.4a, but is not limited to the aforementioned values. L₂ can be 0.1a, 0.2a, 0.3a or 0.35a, but is not limited to the aforementioned values. H₂ can be 0.1a, 0.2a, 0.3a or 0.35a, but is not limited to the aforementioned values.

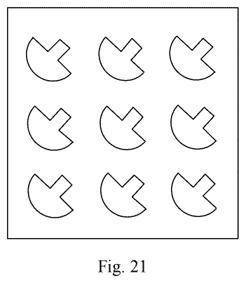

A sectional view of the epitaxial structure according to another embodiment of the present disclosure is shown in FIG. 21 (parallel to the substrate). According to the embodiment in FIG. 21, the first portion 2011 is semi-circular, and the second portion 2012 is rectangular. In other embodiments, the T-shaped pattern can also be consisted of other patterns, and the present disclosure is not intended to limit this.

In an embodiment, right angles, acute angles and obtuse angles in the holes 201 and the filler 202 are chamfered to satisfy the processing requirements.

Obviously, through the disclosure has been described in detail above with reference to the embodiments and drawings, various changes and modifications can still be made by those skilled in the art without to the features recited in the embodiments. It should be understood that those changes and modifications made without departing from the scope and spirit of the present disclosure shall fall within the scope of the disclosure defined by the appended claims.

What is claimed is:

1. A surface-emitting laser, comprising:
a substrate; and
an epitaxial structure;
wherein the substrate and the epitaxial structure are stackedly arranged; the epitaxial structure is provided with a plurality of holes; a section of each of the plurality of holes parallel to the substrate is configured to be T-shaped; each of the plurality of holes is filled with a filler; and a refractive index of the filler is different from a refractive index of the epitaxial structure.

2. The surface-emitting laser according to claim 1, wherein the epitaxial structure comprises a photonic crystal layer and a p-doped cladding layer; the photonic crystal layer and the p-doped cladding layer are stackedly arranged; and the plurality of holes are provided on the photonic crystal layer.

3. The surface-emitting laser according to claim 2, wherein each of the plurality of holes is configured to at least partially extend to the p-doped cladding layer.

4. The surface-emitting laser according to claim 2, wherein the photonic crystal layer comprises a plurality of unit cells arranged in a lattice pattern; the plurality of unit cells are periodically arranged along a first direction and a second direction; each of the plurality of unit cells contains one of the plurality of holes; the section of each of the plurality of holes is symmetrical along a third direction; the first direction, the second direction and the third direction are all parallel to the substrate; the first direction is perpendicular to the second direction; and the third direction is at an angle of 45° to both the first direction and the second direction.

5. The surface-emitting laser according to claim 1, wherein a depth of each of the plurality of holes along a direction perpendicular to the substrate is d, and 50 nm≤d≤500 nm.

6. The surface-emitting laser according to claim 4, wherein the section of each of the plurality of holes comprises a first portion and a second portion connected to each other, and an area of the first portion is larger than an area of the second portion;
a length L₁ of the first portion satisfies 0.35a≤L₁≤1.1a, a width H₁ of the first portion satisfies 0.1a≤H₁≤0.65a, a length L₂ of the second portion satisfies 0.05a≤L₂≤0.35a, and a width H₂ of the second portion satisfies 0.05a≤H₂≤0.35a, wherein a is a lattice constant.

7. The surface-emitting laser according to claim 6, wherein the first portion is elliptical, and the second portion is a rectangular; the length L₁ of the first portion satisfies 0.55a≤L₁≤0.85a; the width H₁ of the first portion satisfies 0.2a≤H₁≤0.5a; the length L₂ of the second portion satisfies 0.1a≤L₂≤0.35a; and the width H₂ of the second portion satisfies 0.1a≤H₂≤0.35a.

8. The surface-emitting laser according to claim 6, wherein the first portion is rhombus-shaped, and the second portion is rectangular; the length L₁ of the first portion satisfies 0.7a≤L₁≤1.1a; the width H₁ of the first portion satisfies 0.3a≤H₁≤0.65a; the length L₂ of the second portion satisfies 0.1a≤L₂≤0.35a; and the width H₂ of the second portion satisfies 0.05a≤H₂≤0.3a.

9. The surface-emitting laser according to claim 6, wherein the first portion and the second portion are both rectangular; the length L₁ of the first portion satisfies 0.5a≤L₁≤0.8a; the width H₁ of the first portion satisfies 0.1a≤H₁≤0.4a; the length L₂ of the second portion satisfies 0.1a≤L₂≤0.35a; and the width H₂ of the second portion satisfies 0.1a≤H₂≤0.35a.

10. The surface-emitting laser according to claim 6, wherein the first portion is roughly elliptical, comprising two straight edges opposite to each other and two curved edges opposite to each other, the two curved edges are each configured to be curved inward, and have a radian of 0 rad-2 rad; the second portion is rectangular, the length L₁ of the first portion satisfies 0.35a≤L₁≤0.85a; the width H₁ of the first portion satisfies 0.15a≤H₁≤0.4a; the length L₂ of the second portion satisfies 0.1a≤L₂≤0.35a; and the width H₂ of the second portion satisfies 0.1a≤H₂≤0.35a.
